(19) United States
(12) Patent Application Publication
(10) Pub. No.: US 2025/0378900 A1
(43) Pub. Date: Dec. 11, 2025

(54) DETERMINING HEALTH OF A NON-VOLATILE MEMORY DEVICE BASED ON A PREDETERMINED DATA PATTERN

(71) Applicant: Microchip Technology Incorporated, Chandler, AZ (US)

(72) Inventors: Nian Niles YANG, Mountain View, CA (US); Pitamber SHUKLA, San Jose, CA (US); Hichem Mohamed BELHADJ, Loomis, CA (US)

(21) Appl. No.: 18/984,990

(22) Filed: Dec. 17, 2024

Related U.S. Application Data
(60) Provisional application No. 63/657,114, filed on Jun. 6, 2024.

(51) Int. Cl. G11C 29/44

(52) U.S. Cl. CPC G11C 29/44

(57) ABSTRACT

In some implementations, a non-volatile memory device may write a first set of values, indicated in a write command, to a first data chunk of the non-volatile memory device, and may further write a second set of values to a second data chunk; perform, based on receiving a health check command, a read operation to read particular data from the second data chunk; determine a measure of variance between the second set of values and the particular data read from the second data chunk of the non-volatile memory device; and output, to a controller of a storage device that includes the non-volatile memory device, a health indication of the non-volatile memory device based on the determined measure of variance between the second set of values and the particular data read from the second data chunk of the non-volatile memory device.

### RELATED APPLICATION

This application claims priority to U.S. Provisional Patent Application No. 63/657,114 entitled “DETERMINING HEALTH OF A NON-VOLATILE MEMORY DEVICE BASED ON A PREDETERMINED DATA PATTERN,” filed Jun. 6, 2024, which is incorporated herein by reference in its entirety.

### FIELD

The present disclosure generally relates to determining the health of a non-volatile memory device and, for example, to determine the health based on a predetermined data pattern (e.g., a predetermined pattern of data).

### BACKGROUND

A non-volatile memory device may include a storage device that may store and retain data without external power supply. One example of a storage device is a NAND flash memory device.

A solid state drive (SSD) may include multiple non-volatile memory devices. A non-volatile memory device (or a die of the non-volatile memory device) may include multiple planes. A plane may include multiple blocks, and a block may include multiple wordlines. A wordline may include one or more pages.

In some situations, the multiple non-volatile memory devices (or dies of the multiple non-volatile memory devices) may form a virtual block (VB). The VB is a collection of blocks (e.g., memory blocks) across all logical unit numbers (LUNs). The size of a VB may be based on a quantity of channels, a quantity of targets, a quantity of LUNs, and a physical block size ([#Channels]×[#Targets]×[#LUNs]×[Physical Block Size]). The size of the VB can potentially vary according to number of bad blocks. The VB includes multiple virtual pages, which is a collection of pages across all LUNs in a VB.

In some situations, a reliability and a stability of the SSD may depend on a detection of a health of the multiple non-volatile memory devices of the SSD. In some situations, a controller of the SSD may determine the health of the multiple non-volatile memory devices.

### SUMMARY

A method comprising: receiving a command to perform a write operation to write a first set of values; writing, based on the command, the first set of values to a first data chunk of a non-volatile memory device; writing, further based on the command, a second set of values to a second data chunk of the non-volatile memory device; after writing the second set of values, receiving a health check command; based on receiving the health check command, performing a read operation to read the data from the second data chunk; comparing, by the non-volatile memory device, the second set of values and the data read from the second data chunk; determining, based on the comparing, a mismatch between the second set of values and the particular data read from the second data chunk; and outputting, by the non-volatile memory device and to a controller of a storage device that includes the non-volatile memory device, a health indication of the non-volatile memory device based on determining the mismatch between the second set of values and the data read from the second data chunk.

A storage device comprising: a controller; and a non-volatile memory device to: receive a command to perform a write operation to write a first set of values; write, based on the command, the first set of values to a first data chunk of the non-volatile memory device; write, further based on the command, a second set of values to a second data chunk of the non-volatile memory device; receive a health check command; based on receiving the health check command, perform a read operation to read data from the second data chunk; compare the second set of values and the data read from the second data chunk; determine, based on the comparing, a mismatch between the second set of values and the data read from the second data chunk, wherein the mismatch is caused by the data of the second data chunk being subjected to change over a period of time; and output, to the controller of the storage device, a health indication of the non-volatile memory device based on the determined mismatch.

A non-transitory computer-readable medium storing a set of instructions, the set of instructions comprising: one or more instructions that, when executed by one or more processors of a non-volatile memory device, cause the non-volatile memory device to: receive a command to perform a write operation to write user data; write, based on the command, the user data to a first data chunk of a block of the non-volatile memory device; write, further based on the command, a predetermined data pattern to a second data chunk of the block; receive a health check command; based on receiving the health check command, perform a read operation to read data from the second data chunk; compare the predetermined data pattern and the data read from the second data chunk; and output, to a controller of a storage device that includes the non-volatile memory device, a health indication of the non-volatile memory device based on comparing the predetermined data pattern and the data read from the second data chunk.

### BRIEF DESCRIPTION OF THE DRAWINGS

FIGS. 1A-1D illustrate an overview of one or more implementations described herein.

FIGS. 2A-2C are flowcharts of an example process for initializing a non-volatile memory device to perform health monitoring operations in accordance with one or more implementations described herein.

FIG. 3 illustrates an example of an example arrangement of data frames of a non-volatile memory device, in accordance with some implementations described herein.

FIG. 4 is a flowchart of an example process for determining the health of a non-volatile memory device based on a predetermined data pattern, in accordance with some implementations described herein.

### DETAILED DESCRIPTION

The following detailed description of example implementations refers to the accompanying drawings. The same reference numbers in different drawings may identify the same or similar elements.

Elements of a storage device, such as a solid state drive (SSD), may provide data regarding the elements of the SSD to a host device associated with the SSD. The data may be provided to the host device based on a command or request from the host device. Such data may be referred to as “telemetry data” (or “SSD telemetry data”). The host device may use the telemetry data to determine operational status metrics (e.g., a “health”) of the SSD.

A controller of the SSD may determine the health of multiple non-volatile memory devices included on the SSD, such as to ensure a stability and a reliability of the SSD. In some situations, performance of the SSD may be negatively affected when the controller performs an operation to determine the health of one or more non-volatile memory devices of the SSD. For example, performing operations to determine the health of the non-volatile memory devices of the SSD may consume bandwidth or other resources of the controller, such that the controller is unable to utilize such bandwidth or resources to perform substantive operations such as reading, writing, or erasing the non-volatile memory devices.

In some cases, the controller may perform an operation to estimate the health of a non-volatile memory device. The controller may, for instance, determine the health of the SSD based on an average value regarding a subset of the non-volatile memory devices. However, because the SSD includes multiple non-volatile memory devices, in order to accurately determine the health of the SSD, the controller would have to determine the heath of all non-volatile memory devices of the SSD. Determining the health of multiple, or all, non-volatile memory devices of the SSD is a relatively time-consuming and potentially computationally complex operation. Accordingly, the controller determining the health of the non-volatile memory devices of the SSD ultimately negatively affects the performance of the SSD, such as by introducing latency and slowing down substantive read, write, and/or erase operations.

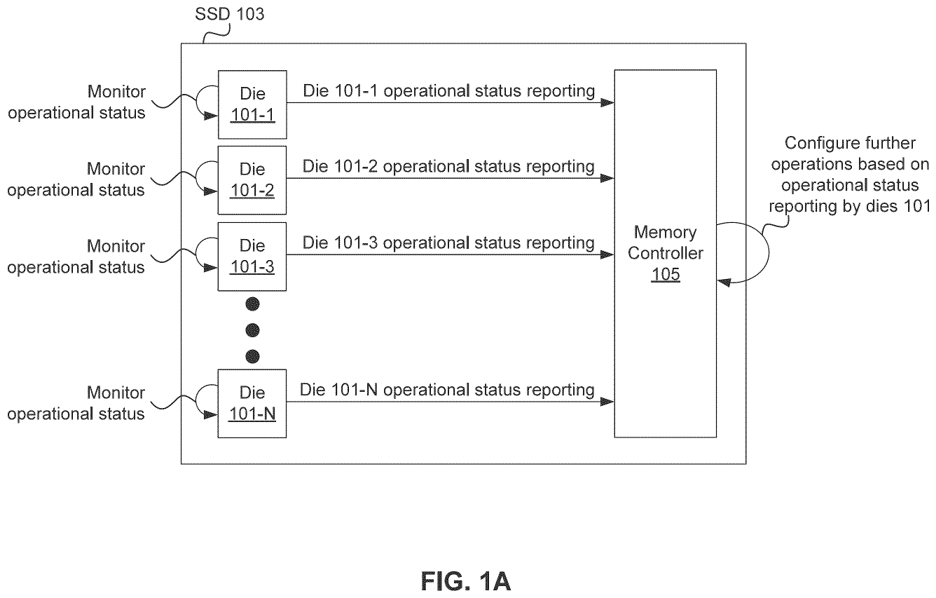

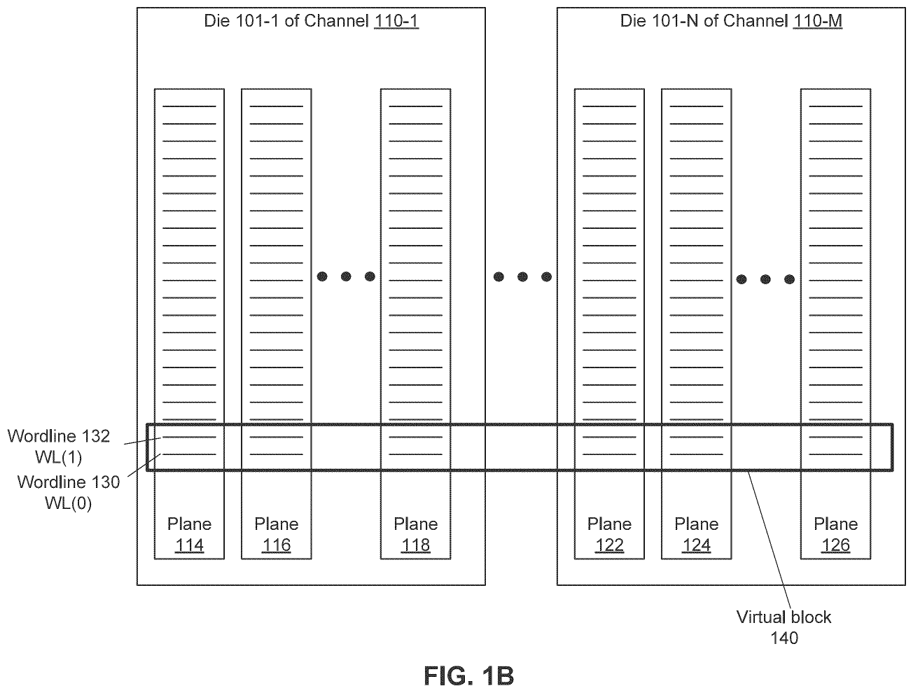

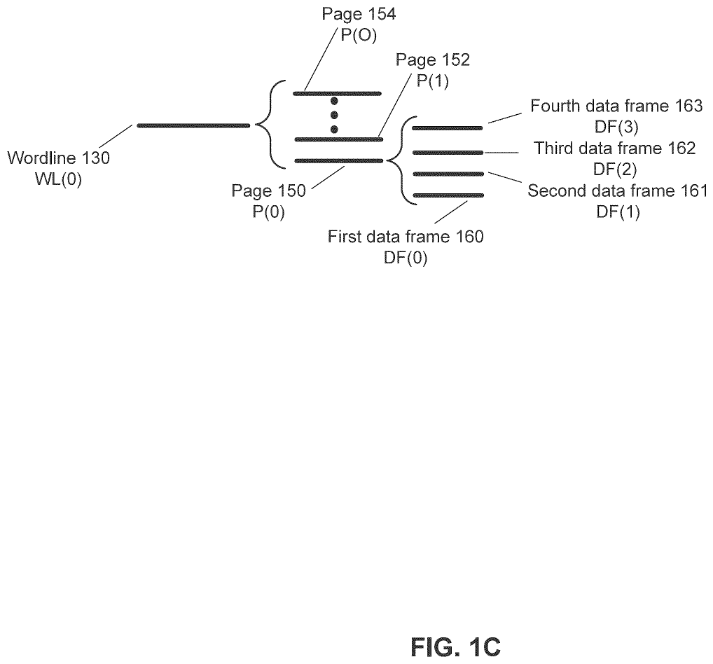

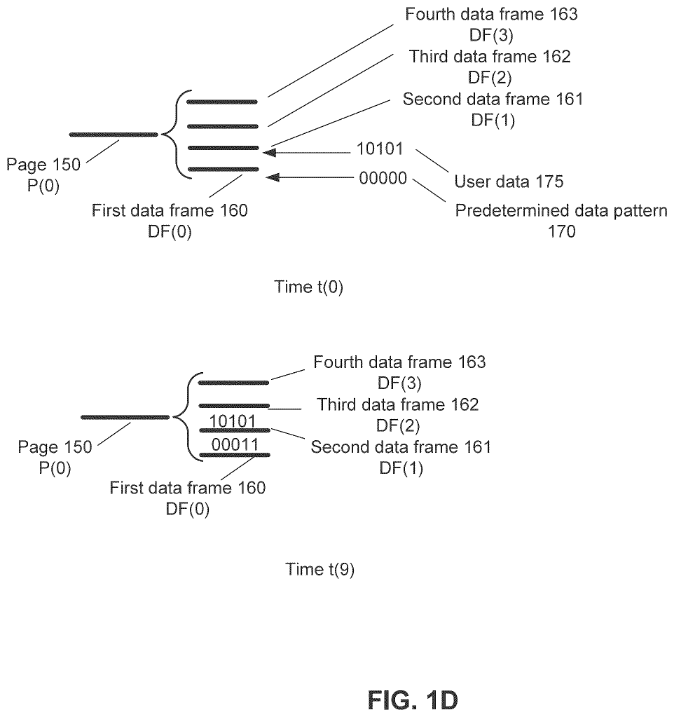

Implementations described herein provide a more efficient mechanism for monitoring the operational status (e.g., “health”) of an SSD, which consumes less controller resources and further provides a greater level of accuracy and precision to the operational status monitoring. For example, as shown in FIG. 1A, individual non-volatile memory devices (e.g., dies 101-1, 101-2, 101-3, 101-N, and so on) of SSD 103 may perform operational status monitoring, such as on a periodic basis, an intermittent basis, an event or command-driven basis, and/or some other suitable basis. Dies 101 may further report the monitored operational status to memory controller 105 of SSD 103. In this manner, memory controller 105 may be kept up-to-date regarding the operational status of dies 101, without needing to perform operations to monitor the operational status of dies 101. As discussed below, memory controller 105 of SSD 103 and/or some other suitable element of SSD 103 may instruct individual dies 101 to perform the operational status monitoring on a more frequent and/or less frequent basis.

Determining the health of the individual non-volatile memory devices (e.g., dies 101) without involving memory controller 105, as described herein, mitigates the negative effect on the performance of SSD 103 discussed above (e.g., utilizing bandwidth/resources of memory controller 105), while ensuring an improved monitoring of the operational status of individual memory elements (e.g., dies 101) in SSD 103. In other words, implementations described herein may enable one or more dies 101, one or more non-volatile memory devices, or the like, to perform their own health check, instead of memory controller 105 performing a system-level monitoring by performing health monitoring operations with respect to each die 101.

As further discussed herein, operational parameters such as data traffic control, scrubbing, ambient conditioning, performance throttling, and/or other types of parameters, may be determined or modified based on the operational status monitoring and reporting by each individual die 101. Additionally, memory controller 105 may modify monitoring parameters, such as instructing particular dies 101 to perform more frequent or less frequent operational status monitoring and/or reporting. In some implementations, memory controller 105 and/or some other suitable device or system that is communicatively coupled to memory controller 105 (e.g., a host device) may utilize artificial intelligence/machine learning (“AI/ML”) techniques to modify such operational parameters (e.g., data traffic control, scrubbing, operational status monitoring intervals, or the like) based on the relative health of one or more dies 101.

In some implementations, as discussed herein, the health of a non-volatile memory device (e.g., a particular die 101) may be determined using a predetermined data pattern written to a data chunk (or data frame) of a block (e.g., a memory block). The predetermined data pattern may serve as an operational status indicator (e.g., a health indicator) for the non-volatile memory device.

As shown in FIG. 1B, a die 101-1 of a channel 110-1 may include planes 114, 116, and 118. Similarly, a die 101-N of a channel 110-M may include planes 122, 124, and 126. The planes 114, 116, 118, 122, 124, 126 may include wordlines. The wordlines may form multiple blocks. In this regard, a plane may include multiple blocks. A block may include multiple wordlines. As shown in FIG. 1B, plane 114 may include multiple wordlines, such as a wordline 130, a worline 132, and so on. As shown in FIG. 1B, multiple wordlines across multiple channels may form a virtual block (VB), such as virtual block 140. As shown in FIG. 1C, wordline 130 may include multiple pages, such as page 150, page 152, and page 154. In some examples, a size of a page may be 16 KB. In other words, a page may include 16 KB of data. A block may include a single page, a portion of a single page, or multiple pages. A page may include multiple data frames (also referred to as data chunks or chunks of data). As shown in FIG. 1C, page 150 may include 4 data frames, such as a first data frame 160, a second data frame 161, a third data frame 162, and a third data frame 163. As shown in FIG. 1D, a predetermined data pattern 170 (also referred to as “health monitoring data pattern”) may be written to first data frame 160 and user data 175 (also referred to as host data) may be written to another data frame. For example, when a controller (e.g., memory controller 105) writes user data to a block of the non-volatile memory, the controller may generate predetermined data pattern 170 and may write predetermined data pattern 170 during a write operation to write user data 175 to the non-volatile memory device. A value of predetermined data pattern 170, shown in FIG. 1D, is merely an example. Other values may be used for predetermined data pattern 170. When a host device that is communicatively coupled to the SSD requests access to data (e.g., user data) stored by the block, first data frame 160 may be skipped and other data frames may be accessed. For example, the controller may send data from second data frame 161, third data frame 162, and/or third data frame 163 and may forgo sending data from first data frame 160 to the host device. In this manner, the host device may, in some implementations, be “unaware” of such data frame that includes predetermined data pattern 170, and/or of the predetermined data pattern itself.

In some situations, the health check may be triggered based on either a host request, an internally scheduled health monitoring of the SSD, or some other suitable situation. In some implementations, the controller of the SSD may issue a health check command to the non-volatile memory device associated with the controller of the SSD (e.g., to die 101-1). The controller may issue the health command based on a period of time (e.g., on a periodic interval), based on a change in temperature of the non-volatile memory device, based on a quantity of program/erase cycles associated with the non-volatile memory device, based on decoding failures of data from the host device, among other examples. The health check command may be devoid of (e.g., may not include, and/or may omit) a command to record or provide data to the non-volatile memory devices (e.g., dies 101). In other words, in some implementations, the health check command may be separate from, or independent of, a write command for writing user data to the non-volatile memory device. For example, in such implementations, the host device or SSD controller may not cause user data to be provided to the non-volatile memory devices as part of the health check command. Rather, the non-volatile memory device (e.g., die 101-1) may internally read the location where the predetermined data pattern is stored, and may compare the data read from the location with the predetermined data pattern. For example, die 101-1 may read data from first data frame 160 and may compare the read data and predetermine data pattern 170, Since the predetermined data pattern is predefined (e.g., by the system, the controller, the non-volatile memory device, or any suitable combination), comparing the read data (e.g., read from first data frame 160) and predetermined data pattern 170 may indicate whether any errors are present with respect to the non-volatile memory device.

For example, based on the comparison, the non-volatile memory device, in some situations, may determine a mismatch between the data read from the location that initially stored predetermined data pattern 170 (e.g., first data frame 160) and predetermined data pattern 170. As shown in FIG. 1D, predetermined data pattern 170 may be stored in first data frame 160 at time t(0). Over a period of time, data stored in first data frame 160 may be subjected to data retention degradation or read disturbance. In some examples, first data frame 160 may be a first (or oldest) physical location written on the block. For instance, first data frame 160 may be a first page of a wordline of a block. Accordingly, first data frame 160 may be more likely to be subjected to data retention degradation and read disturbance. Therefore, first data frame 160 may be a good proxy for the health of the block. As used herein, “data retention degradation” may refer to a degraded (or decreased) data retention of the non-volatile memory device due to loss of electrons occurring during a power-off condition of the memory device. The loss of electrons may affect threshold voltages. Accordingly, “data retention degradation” may indicate a change in threshold voltages as a result of the loss of electrons. As used herein, “read disturb” (or “read disturbance” or “read disturb event”) may be used to refer to a change in a threshold voltage of a memory cell resulting from an electrical charge applied to an adjacent (or neighboring) memory cell during one or more read operations to read data from the adjacent cell.

Accordingly, over a period of time, first data frame 160 may be subjected to data retention degradation and/or read disturbance. Accordingly, the data (stored in first data frame 160) may change. For example, at time t(9), the data stored in first data frame 160 may be different than predetermined data pattern 170 originally stored in first data frame 160. The non-volatile memory device may compare predetermined data pattern 170 and the data read from first data frame 160 to determine a mismatch between predetermined data pattern 170 and the data. For example, the non-volatile memory device may compare the data stored in first data from 160 (e.g., “00011”) and predetermine data pattern 170 (“00000”) and determine the mismatch. The non-volatile memory device may determine whether the mismatch satisfies a mismatch threshold set by the system (e.g., determine if the mismatch exceeds the mismatch threshold). The mismatch threshold may essentially include a bit error rate by comparing the read data and the predetermined data pattern. The bit error rate may be a function of, for example, a quantity of bits associated with the location storing predetermined data pattern 170, and a quantity of bits of the read data that match (and/or do not match), in a bitwise manner, the predetermined data pattern. In some implementations, the quantity of bits associated with the location storing the predetermined data pattern may include 17,000 bits or some other suitable quantity of bits.

In some implementations, the operational status reporting of each non-volatile memory device (e.g., each die 101) to memory controller 105 may be performed in response to a “status read” command issued to each non-volatile memory device to check the internal readout status of the non-volatile memory device. Based on the result from the non-volatile memory device, returned in response to the “status read,” the controller may determine the health of the non-volatile memory device. For example, if the mismatch satisfies the mismatch threshold, the controller may determine that the health of the non-volatile memory device may negatively affect reliability and integrity of data stored by the non-volatile memory device. As described herein, the more lengthy or complex health checking operations (e.g., a bitwise comparison of read data to a predetermined data pattern) may be performed by individual dies 101, without consuming bandwidth or other resources of memory controller 105.

In situations where host operations are to be performed with respect to the non-volatile memory device (e.g., a read command issued by a host device, a write command issued by a host device, an erase command issued by a host device, or the like), an ongoing operation to read the data frame that stores the predetermined data pattern may be terminated without any impact on the performance of SSD 103. In this manner, the operational status monitoring of some implementations may be “non-obtrusive” with respect to host operations of SSD 103, thus minimizing or eliminating the performance impact of performing the operational status monitoring.

Further, the operations described herein may be performed for all non-volatile memory devices included on SSD 103. In this regard, health monitoring of the non-volatile memory devices (of SSD 103) may be performed in parallel. For example, the operations described herein may contemporaneously and/or simultaneously be performed on multiple blocks, non-volatile memory devices, dies 101, or the like.

Implementations described herein further enable a ranking and/or other analysis mechanism that improves the SSD monitoring process based on an ongoing monitoring data acquisition and, as discussed above, may enable the use of automated techniques such as AI/ML techniques to provide improved options for configuring operations with respect to SSD 103 by a host device. The ranking and/or other analysis may be based on, for example, operational status information from multiple (e.g., some or all) dies 101 of SSD 103. Based on the ranking, particular dies 101 that are “weaker” than other dies 101 or that have a tendency to become weaker may be identified. Based on identifying such weaker dies, telemetry checkups may be issued more frequently for the identified weaker dies. As another example, operations such as write operations may be performed less frequently to the weaker dies than to other dies. As another example, operations such as data recovery operations may be performed with respect to the weaker dies. Accordingly, implementations described herein may provide more accurate, more reliable, more on the-fly real-time quality check and quality prediction for the non-volatile memory device.

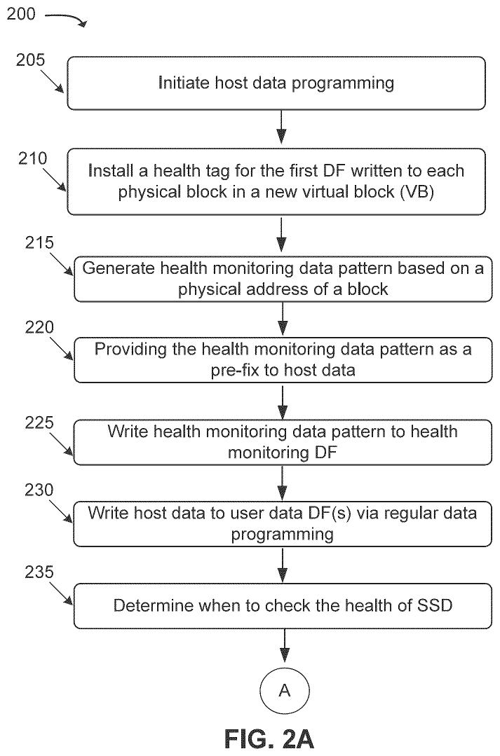

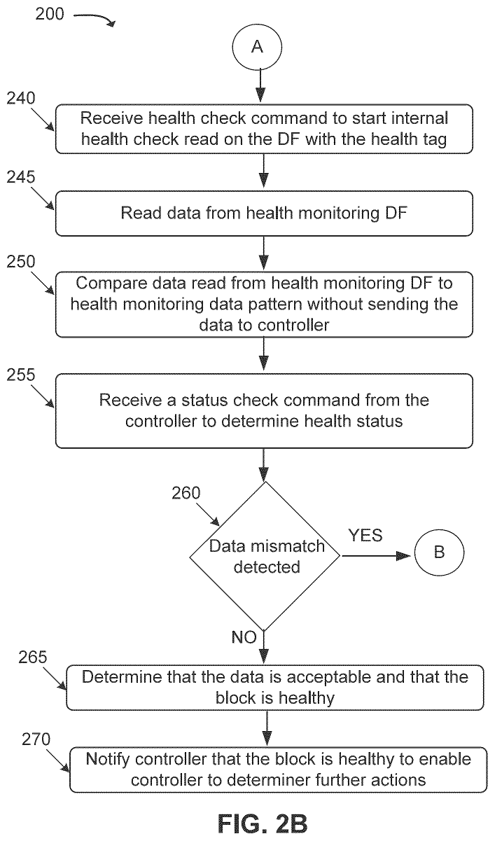

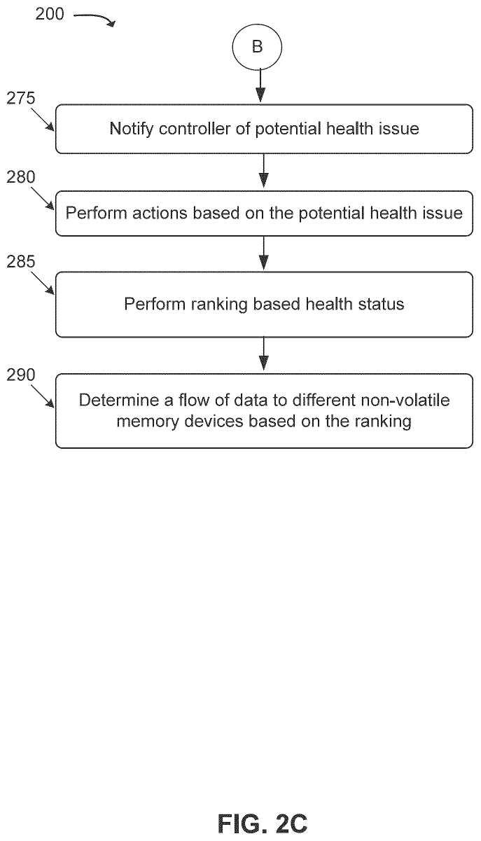

FIGS. 2A to 2C are flowcharts of an example process 200 for initializing one or more elements of a storage device (e.g., one or more dies 101 of SSD 103) to ultimately perform the operational status monitoring operations described herein. In some implementations, one or more process blocks of FIGS. 2A-2C may be performed by a controller of a storage device, such as memory controller 105 of SSD 103. Thus, while process 200 is described in the context of memory controller 105, in practice, some or all of process 200 may be performed by some other suitable device (e.g., a host device that is communicatively coupled to SSD 103), or element of a storage device.

As shown in FIG. 2A, process 200 may include a host data programming being initiated (at block 205). As shown in FIG. 2A, process 200 may include installing a health tag for the first DF written to each physical block in a new virtual block (VB) (at block 210). For example, process 200 may include installing a “health tag” to one or more particular data chunks or data frames (“DFs”) of one or more dies 101. For example, for any new virtual block to be written to SSD 103, one or more dies 101 on which the virtual block is implemented may be initialized with the health tag. Installing the health tag may include designating or assigning a particular DF, such as a “prefix” DF or some other DF (referred to herein as the “health monitoring DF”), of a block of die 101 for health monitoring purposes. As explained herein, the health tag may be designed for a first DF first (or oldest) physical location written on a physical block. Other (e.g., subsequent) DFs of the block of die 101 may be used for host operations. For example, data written to die 101, as requested from a host device, may be written to the other DFs, but not to the health monitoring DF. In this regard, the health monitoring DF may be a read-only DF from the standpoint of the host device, in some implementations. In some implementations, the health monitoring DF may not be visible and, accordingly, not accessible to the host device. In some embodiments, the health monitoring DF may be a DF other than a first, or initial, DF of die 101 (e.g., a last DF or a DF between the first and last DF of die 101). In this context, the “first” DF of die 101 may refer to a DF to which data is written first, in a sequential order of writing data to a group of DFs of die 101.

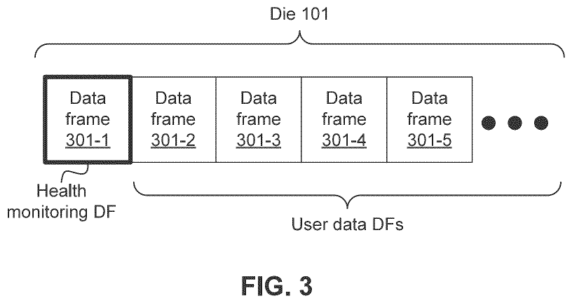

FIG. 3 illustrates an example die 101 that includes a set of DFs 301 (e.g., DFs 301-1, 301-2, 301-3, 301-4, 301-5, and so on). One particular DF 301 (i.e., the first DF 301-1, in this example) may be designated as the health monitoring DF of die 101, while some or all of the other DFs 301 (i.e., DFs 301-2 onward, in this example) may be designated as “user data” DFs, and/or may otherwise not be designated as a health monitoring DF.

Process 200 may further include generating a health monitoring data pattern based on a physical address of a block (at block 215). For example, memory controller 105 may generate a data pattern (referred to as a “health monitoring data pattern”), which may be a 4 KB data pattern or a data pattern of some other size. Memory controller 105 may utilize a set of parameters, an algorithm, an equation, and/or a function to generate the health monitoring data pattern. In some examples, the health monitoring data pattern may be based on the physical address of the block. For example, the physical address may be a variable that is used in the algorithm, the equation, and/or the function to generate the health monitoring data pattern. In some examples, the health monitoring data pattern may be generated by the non-volatile memory device as described herein

Process 200 may also include providing the health monitoring data pattern as a pre-fix to host data (at block 220). For example, memory controller 105 may provide the health monitoring data pattern pre-fixed to host data (or user data). In other words, the health monitoring data pattern may be prepended to the host data. In this regard, when providing the health monitoring data pattern and the host data for storage on a block, the health monitoring data pattern may be stored in a DF (of the block) with a health tag and the host data may be stored in one or more other DFs of the block. Process 200 may also include writing the health monitoring data pattern to health monitoring DF (at block 225). For example, memory controller 105 may provide the health monitoring data pattern to die 101, which may include configuring a firmware of die 101, an application-specific program circuit (ASIC) of die 101, and/or some other suitable element of die 101 with the health monitoring data pattern. Additionally, or alternatively, programming the die with the health monitoring data pattern may include providing a set of parameters, an algorithm, a function, or the like, which may be invoked or executed by die 101 to reliably reproduce the health monitoring data pattern. In some embodiments, the set of parameters, algorithm, and/or function may be the same as the parameters, algorithm, and/or function used by memory controller 105 (e.g., at block 215) to generate the health monitoring data pattern. In this manner, die 101 may be able to reproduce the health monitoring data pattern at a later time, as discussed below. In some examples, memory controller 105 may receive a request from a host device or some other suitable source to write data (e.g., host data) to SSD 103, and memory controller 105 may select a die 101 as a destination for the data. Memory controller 105 may write the health monitoring data pattern to the health monitoring DF prior to writing the host data.

In some implementations, writing data to the die may include writing the health monitoring data pattern to the health monitoring DF of the block die 101 (e.g., DF 301-1 in the example of FIG. 3). For example, this may be an initial iteration of writing the health monitoring data pattern to the health monitoring DF, out of potentially many iterations.

Returning to FIG. 2, process 200 may also include writing host data to user DF(s) via regular data programming (at block 230). Writing the data to the die may include, as noted above, writing the data to one or more DFs of the block, other than the health monitoring DF (e.g., writing the data to DFs 301-2, 301-3, and so on rather than to DF 301-1).

Writing the data to the die may include, as noted above, writing the data to one or more DFs of the block, other than the health monitoring DF (e.g., writing the data to DFs 301-2, 301-3, and so on rather than to DF 301-1). For example, memory controller 105 may avoid selecting the health monitoring DF (e.g., DF 301-1), as the health monitoring DF is used for the health monitoring implementations described herein. Additionally, or alternatively, memory controller 105 may select die 101 as the destination for the data, and circuitry within die 101 (e.g., an ASIC) may write the data to one or more user data DFs (e.g., not to a health monitoring DF of die 101).

In some implementations, memory controller 105 may instruct die 101 to write the health monitoring data pattern to the health monitoring DF of die 101. Such instruction, from memory controller 105, may be issued by memory controller 105 in conjunction with, subsequent to, or otherwise based on the writing of the data (at block 230) to the one or more user data DFs of die 101. In some implementations, memory controller 105 may write the health monitoring data and the data (e.g., host data) on the same wordline. In some implementations, the instruction to write the health monitoring pattern to the health monitoring DF of die 101 may include the actual health monitoring pattern itself. In some implementations, circuitry within die 101 may identify or generate (e.g., re-generate) the health monitoring data pattern (e.g., based on the programming at block 215), and write the health monitoring data pattern in conjunction with the writing of the user data to one or more user data DFs. In such implementations, controller 105 may invoke or execute the set of parameters, algorithm, function, or the like (e.g., as programmed at block 215), to reproduce the health monitoring data pattern. Controller 105 may reproduce or re-generate the health monitoring data pattern in this manner in implementations where an instruction from controller 105 (e.g., as discussed above) does not include the health monitoring pattern itself.

In this manner, in some or all instances where data is written to die 101, the health monitoring data pattern may be written or re-written to the health monitoring DF of die 101. For example, blocks 220 and 225 may be performed multiple times with respect to some or all dies 101 of SSD 103. Since the health monitoring data is written to the health monitoring DF of die 101 in conjunction with the writing of user data to one or more user data DFs of die 101, the writing of the health monitoring data to the health monitoring DF may be relatively “low overhead” in terms of time and/or processing resources, as die 101 is already being instructed to perform one or more write operations.

Process 200 may also include determining when to check the health of the SSD (at block 230). Memory controller 105 may determine to check the health of the block based on various triggers. The triggers may include a periodic interval, a change in temperature of the non-volatile memory device, a quantity of program/erase cycles associated with the non-volatile memory device (or associated with the block), based on decoding failures of data from the host device, among other examples. As described herein, the health of a block (of a die 101 of SSD 103) may be determined based on data stored by the health monitoring DF.

As shown in FIG. 2B, process 200 may also include receiving a health check command to start internal health read on the DF with the health tag (at block 240). For example, die 101 may receive the health check command from memory controller 105. Memory controller 105 and/or some other suitable device (e.g., a host device that is communicatively coupled to SSD 103) may determine that the health check command should be issued based on a timestamp of a last health check or operational status report from die 101, program/erase cycle amount associated with die 101, change in temperature of die 101, decoding failures of data from the host device, and/or other suitable factors or triggering events.

The health check command may include a special test mode command or some other suitable command (e.g., issued by memory controller 105) to instruct die 101 to start the internal health check read (e.g., to read the health monitoring DF). Die 101 may be capable of operating in a test mode that enables die 101 to initiate the health check The test mode may enable die 101 to read the health monitoring DF and, accordingly, respond to the test mode command. The test mode may be triggered based on die 101 receiving the health check command. For example, the health check command may include information that triggers the test mode to cause die 101 to read the health monitoring DF. Process 200 may also include reading data from the health monitoring DF (at block 245). For example, based on receive the health check command, die 101 may read the data stored in the health monitoring DF. For example, die 101 may apply a sensing operation to the health monitoring DF only (e.g., to a wordline and/or page to which the health monitoring DF belongs) in order to read the data. For instance, based on the health check command, die 101 may read data stored on the health monitoring DF (e.g., first data frame 160). As discussed above, the data may have been written to the health monitoring DF (e.g., first data frame 160) in conjunction with a write operation performed on die 101 (e.g., in conjunction with a write operation to write host data on the block as discussed above with respect to block 225 and block 230).

Process 200 may further include comparing the data read from the health monitoring DF to the health monitoring data pattern without sending the data to the controller (at block 4250). For example, as discussed above, die 101 may be able to generate, re-create, or otherwise identify the health monitoring data pattern in order to compare the health monitoring data pattern to the data read from the health monitoring DF (e.g., first data frame 160). The health monitoring data pattern may include a first set of values and the data read from the health monitoring DF may include a second set of values. As discussed above, the comparison may include a bitwise comparison or some other suitable type of comparison or similarity analysis. The comparison may, in some implementations, be performed without sending data to memory controller 105.

Process 200 may further include receiving a status check command from the controller to determine health status (at block 255). Based on the status check command, die 101 may determine a health status of die 101 based on the comparison of the data read from the health monitoring DF and the health monitoring. Process 200 may further include determining whether data mismatched is detected (at block 260). For example, die 101 (e.g., circuitry of die 101 such as an ASIC) may determine a measure of change (e.g., a measure of variation) between the value read from the health monitoring DF and the health monitoring data pattern. As one example, the measure of change may include a quantity of bits that were different between the value read from the health monitoring DF and the health monitoring data pattern. As another example, the measure of variation may include a proportion of percentage of bits that were different between the value read from the health monitoring DF to the health monitoring data pattern. In some embodiments, the measure of variation may be based on whether the variation between the value read from the health monitoring DF and the health monitoring data pattern exceeds one or more thresholds (e.g., at least a threshold quantity or proportion of differing bits).

Process 200 may further include determining that the data is acceptable and that the block is healthy (at block 265). Based on the comparison, die 101 may determine that the data is acceptable. For example, die 101 may determine that the measure of change does not exceed a change threshold. Accordingly, die 101 may determine that the block is healthy. Process 200 may further include notifying the controller that the block is healthy to enable the controller to determine further actions (at block 270). Based on determining that the data is acceptable and that the block is healthy, die 101 may provide a notification to the controller. For example, die 101 may output a binary indication denoting “healthy” or “not healthy,” such as in implementations where die 101 determines whether a variation between the value read from the health monitoring DF and the health monitoring data pattern is lower than a change threshold. In some implementations, die 101 may indicate one or more raw data values, such as a quantity or proportion of bits that differ in the value read from the health monitoring DF and the health monitoring data pattern. In some embodiments, die 101 may output some other raw or derived value, based on the comparing, to memory controller 105.

In certain situations, die 101 may be considered healthy (e.g., as indicated by die 101 as a binary value and/or as determined by memory controller 105 based on further analysis of information provided by die 101 in response to the health status request), and monitoring of die 101 may continue to verify that its operational status remains nominal (e.g., healthy).

As shown in FIG. 2C, process 200 may also include notifying the controller of a potential health issue (at block 275). For example, based on the comparison, die 101 may determine that the data is unacceptable. For example, die 101 may determine that the measure of change exceeds the change threshold. Accordingly, die 101 may determine that the block is unhealthy (e.g., the block is experiencing the potential health issue). In this regard, in certain situations, die 101 may be considered unhealthy (e.g., as indicated by die 101 as a binary value and/or as determined by memory controller 105 based on further analysis of information provided by die 101 in response to the health status request). Die 101 may be considered as experiencing the potential health issue.

Process 200 may also include performing actions based on the potential health issue (at block 280). For example, in the event that die 101 is considered unhealthy (e.g., based on an identified data mismatch with respect to the value read from the health monitoring DF and the health monitoring data pattern) memory controller 105 and/or a host device may become aware of the potential health issue, and further action can be taken to handle such issues. The further action may include read scrubbing, data relocation, and/or other suitable measures.

Process 200 may also include performing a ranking based on a health status (at block 285). For example, memory controller 105 may determine that the health status of die 101 is that die 101 is unhealthy. Additionally, in some implementations, dies 101 (including die 101 whose health status was determined) may be ranked (e.g., by memory controller 105 or a host device). Such ranking may, for example, be based on the health monitoring information received from each die 101 (e.g., which may be based on a measure of variation between values read from the health monitoring DF of each die 101 and the health monitoring data pattern). For instance, a first die 101 with a relatively low measure of variation may be considered more healthy and may accordingly be ranked more highly, while a second die with a relatively high measure of variation may be considered less healthy and may accordingly be ranked lower.

These rankings may influence operations by memory controller 105 and/or the host device, such as selections of particular dies 101 to which data should be written. As noted above, AI/ML techniques may be used for using the health monitoring data at different time intervals and program erase cycle intervals, to best manage the SSD usage and quality management (such as data traffic control, scrubbing, ambient conditioning, and performance throttling). Process 200 may also include determine a flow of data to different non-volatile memory devices based on the ranking (at block 290). For example, the controller 105 may provide data (to be stored) to one or more dies 101 that are ranked higher than the current die 101. In other words, the controller 105 may provide the data to healthier and more reliable dies 101 for storage.

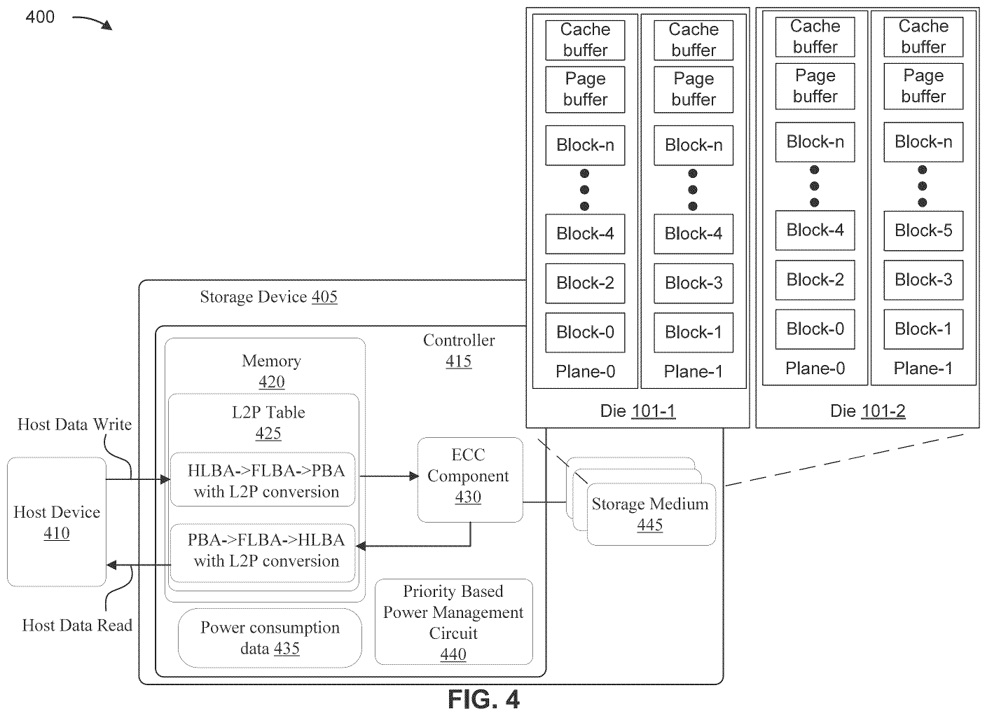

Although FIGS. 2A-2C show example blocks of process 200, in some implementations, process 200 may include additional blocks, fewer blocks, different blocks, or differently arranged blocks than those depicted in FIG. 4. Additionally, or alternatively, two or more of the blocks of process 200 may be performed in parallel.

FIG. 4 is a diagram of an example implementation 400 described herein. Example implementation 400 describes components and operations associated with a storage device 405. In some implementations, storage device 405 may include an SSD. For example, in some implementations, storage device 405 may be, may include, may implement, and/or may otherwise be associated with SSD 103. As shown in FIG. 4, storage device 405 may be associated with a host device 410. Host device 410 may access data, such as “host data” or “user data,” stored by storage device 405. For example, as shown in FIG. 5, host device 510 may initiate a host data write operation (e.g., a write operation) to write the host data to storage device 405 (e.g., to store the data on storage device 405) and may initiate a host read operation (e.g., a read operation) to read the host data from storage device 405.

Host device 410 may include one or more devices capable of receiving, generating, storing, processing, and/or providing information associated with generating a logical-to-physical (L2P) data structure (or L2P table). Host device 410 may include a communication device and a computing device. For example, host device 410 may include a wireless communication device, a mobile phone, a user equipment, a laptop computer, a tablet computer, a desktop computer, a wearable communication device (e.g., a smart wristwatch, a pair of smart eyeglasses, a head mounted display, or a virtual reality headset), or a similar type of device.

As shown in FIG. 4, storage device 405 may include a controller 415. Controller 415 may include one or more of an ASIC or firmware. In some embodiments, controller 415 may be, may implement, may be implemented by, and/or may otherwise include memory controller 105. Controller 415 may cause functions to be performed on storage device 405, such as read operations, write operations, erase operations, garbage collection operations, among other examples. Controller 415 may include a memory 420 and an error correction code (ECC) component 430. Memory 420 may include a RAM (e.g., dynamic random access memory (DRAM), a synchronous DRAM (SDRAM), among other examples).

As shown in FIG. 4, memory 420 may include L2P table 425 (or an L2P data structure). L2P table 425 may store a mapping between host logical block addresses (or logical addresses identified by host device 410) and physical block addresses (or physical addresses of non-volatile memory devices of storage device 405). In some implementations, L2P table 425 may be generated by controller 415.

In some implementations, controller 415 may identify a host logical block address (HLBA) associated with the host data by which host device 410 may reference the host data in a future read operation. As shown in FIG. 4, controller 415 may convert the HLBA to a flash logical block address (FLBA) or other local logical block address, and then may link the FLBA to a physical block address (PBA) using an L2P conversion. Conversely, controller 415 may convert a PBA to an FLBA or other local logical block address, and then may link the FLBA to a physical block address (PBA) using an L2P conversion. In this way, the host device may send a static address associated with the host data, controller 415 may link the address known to host device 410 to an address known to storage device 405 (the FLBA), and may link the address known to storage device 405 to a physical address of the host data within a storage medium of storage device 405.

Controller 415 may store the links between the HLBA, the FLBA, and the PBA in L2P table 425. In some aspects, the host data may be moved within the storage medium or between storage media of storage device 405, which controller 415 may note in the link between the FLBA and the physical location. In this way, the HLBA may bypass being updated when the host data is moved to a new PBA.

ECC component 430 may include an ECC engine. ECC component 430 may perform error correction code encoding on the host data. In some implementations, the error correction code encoding may include adding redundancy, parity bits, or other information that can later be used to identify errors in the host data when read from the storage medium. Controller 415 may provide the host data, after encoding, via flash control channels (not shown) to write on storage media of storage device 405. In some implementations, ECC component 430 may perform decoding on data obtained from storage device 405.

As shown in FIG. 4, controller 415 may include power consumption data 435. Power consumption data 435 may be stored in a memory of ccc, such as memory 420, another memory, or a combination of the foregoing. In some implementations, power consumption data 435 may be stored in a memory external with respect to controller 415. Power consumption data 435 may include information regarding power consumption by different operations performed by different components of storage device 405. In some implementations, power consumption data 435 may include information regarding an amount of power consumed by different operations (e.g., erase operations, read operations, write operations, garbage collection operations, without limitation).

In some implementations, power consumption data 435 may include information regarding an amount of power consumed by different portions of an operation (e.g., a beginning of the operation, an ending of the operation, without limitation). In some implementations, power consumption data 435 may include information regarding an amount of power consumed by different dies (e.g., 128 dies), an amount of power consumed by power consumption by one or more DRAMs, an amount of power consumed by power consumption by one or more static RAMs, without limitation.

As shown in FIG. 4, controller 415 may include a priority based power management circuit 440 (also referred to as “power management circuit 440”). Power management circuit 440 may manage power consumed by storage device 4405 by suspending and resuming operations performed on storage device 4405. As described herein, power management circuit 440 may calculate, using power consumption data 435, power consumed by one or more ongoing operations, determine priorities associated with the one or more ongoing operations and an upcoming operation, and suspend the one or more ongoing operations to initiate the upcoming operation based on the power consumed and the priorities.

As shown in FIG. 4, storage device 4405 may include storage media 445 (individually “storage medium 445” and collectively “storage media 445”). A storage medium 445 may include a non-volatile memory device. For example, the storage medium 445 may include a NAND memory device. In some situations, storage media 445 may be organized by data pools. A “data pool” may be used to refer to part of a storage medium 445 that stores a given type of data (e.g., SLC data, MLC data, and TLC data, without limitation).

As shown in FIG. 4, a storage medium 445 may include multiple dies 101. In some implementations, a particular die 101 may include multiple planes. A plane may include multiple memory blocks (also referred to as “block”), one or more page buffers (associated with the blocks), and one or more cache buffers.

As indicated above, FIG. 4 is provided as an example. Other examples may differ from what is described with regard to FIG. 4. The number and arrangement of devices shown in FIG. 4 is provided as an example. In practice, there may be additional devices, fewer devices, different devices, or differently arranged devices than those shown in FIG. 4. Furthermore, two or more devices shown in FIG. 4 may be implemented within a single device, or a single device shown in FIG. 4 may be implemented as multiple, distributed devices. Additionally, or alternatively, a set of devices (e.g., one or more devices) shown in FIG. 4 may perform one or more functions described as being performed by another set of devices shown in FIG. 4.

As used herein, the term “component” is intended to be broadly construed as hardware, firmware, or a combination of hardware and software. It will be apparent that systems or methods described herein may be implemented in different forms of hardware, firmware, or a combination of hardware and software. The actual control hardware or software code used to implement these systems or methods is not limiting of the implementations. Thus, the operation and behavior of the systems or methods are described herein without reference to specific software code-it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with other claims in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein is to be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method comprising:
receiving a command to perform a write operation to write a first set of values;
writing, based on the command, the first set of values to a first data chunk of a non-volatile memory device;
writing, further based on the command, a second set of values to a second data chunk of the non-volatile memory device;
after writing the second set of values, receiving a health check command;
based on receiving the health check command, performing a read operation to read the data from the second data chunk;
comparing, by the non-volatile memory device, the second set of values and the data read from the second data chunk;
determining, based on the comparing, a mismatch between the second set of values and the particular data read from the second data chunk; and
outputting, by the non-volatile memory device and to a controller of a storage device that includes the non-volatile memory device, a health indication of the non-volatile memory device based on determining the mismatch between the second set of values and the data read from the second data chunk.

2. The method of claim 1, wherein the storage device includes a solid state drive (SSD) that includes the controller,
wherein comparing the comparing second set of values and the data read from the second data chunk of the non-volatile memory device comprises comparing the second set of values and the data without using the controller.

3. The method of claim 2, wherein the controller outputs a plurality of health check commands based on at least one of:
a periodic interval,
a change in temperature of the non-volatile memory device, or
a quantity of program/erase cycles associated with the non-volatile memory device.

4. The method of claim 1, wherein the second data chunk comprises a physical location, of the non-volatile memory device, that is first written when a first write operation is performed on the non-volatile memory device with respect to a sequential order of performing write operations on the non-volatile memory device.

5. The method of claim 1, further comprising:
determining whether the mismatch, between the second set of values and the data read from the second data chunk of the non-volatile memory device, exceeds a mismatch threshold,
wherein outputting the health indication includes outputting an indication of whether the measure of variance, between the second set of values and the data read from the second data chunk of the non-volatile memory device, exceeds the mismatch threshold.

6. The method of claim 1, wherein the second data chunk comprises a first page of a first wordline of a block of a plurality of blocks of the non-volatile memory device.

7. The method of claim 1, wherein the first set of values includes user data,
wherein the second set of values include a predetermined data pattern, and
wherein the second set of values is not included in the command to write the first set of values.

8. The method of claim 1, wherein the first data chunk and the second data chunk are included on a block, and
wherein the method further comprises:
ranking the non-volatile memory device based on the health indication.

9. A storage device comprising:
a controller; and
a non-volatile memory device to:
receive a command to perform a write operation to write a first set of values;
write, based on the command, the first set of values to a first data chunk of the non-volatile memory device;
write, further based on the command, a second set of values to a second data chunk of the non-volatile memory device;
receive a health check command;
based on receiving the health check command, perform a read operation to read data from the second data chunk;
compare the second set of values and the data read from the second data chunk;
determine, based on the comparing, a mismatch between the second set of values and the data read from the second data chunk,
wherein the mismatch is caused by the data of the second data chunk being subjected to change over a period of time; and
output, to the controller of the storage device, a health indication of the non-volatile memory device based on the determined mismatch.

10. The storage device of claim 9, wherein the storage device includes a solid state drive (SSD) that includes the controller,
wherein, to compare the comparing second set of values and the data read from the second data chunk, the non-volatile memory device is to compare the second set of values and the data without using the controller.

11. The storage device of claim 10, wherein the controller outputs a plurality of health check commands based on at least one of:
a periodic interval,
a change in temperature of the non-volatile memory device, or
a quantity of program/erase cycles associated with the non-volatile memory device.

12. The storage device of claim 9, wherein the second data chunk comprises a physical location, of the non-volatile memory device, that is first written when a first write operation is performed on the non-volatile memory device with respect to a sequential order of performing write operations on the non-volatile memory device.

13. The storage device of claim 9, wherein the non-volatile memory device is further to:
determine whether the mismatch exceeds a mismatch threshold,
wherein, to output the health indication, the non-volatile memory device is to output an indication of whether the mismatch exceeds the mismatch threshold.

14. The storage device of claim 9, wherein the second data chunk comprises a first page of a first wordline of a block of a plurality of blocks of the non-volatile memory device.

15. The storage device of claim 9, wherein the first set of values includes user data.

16. The storage device of claim 9, wherein the second set of values is not included in the command to write the first set of values.

17. A non-transitory computer-readable medium storing a set of instructions, the set of instructions comprising:
one or more instructions that, when executed by one or more processors of a non-volatile memory device, cause the non-volatile memory device to:
receive a command to perform a write operation to write user data;
write, based on the command, the user data to a first data chunk of a block of the non-volatile memory device;
write, further based on the command, a predetermined data pattern to a second data chunk of the block;
receive a health check command;
based on receiving the health check command, perform a read operation to read data from the second data chunk;
compare the predetermined data pattern and the data read from the second data chunk; and
output, to a controller of a storage device that includes the non-volatile memory device, a health indication of the non-volatile memory device based on comparing the predetermined data pattern and the data read from the second data chunk.

18. The non-transitory computer-readable medium of claim 17, wherein the storage device includes a solid state drive (SSD) that includes the controller,
wherein the one or more instructions to compare the predetermined data pattern and the data read from the second data chunk comprise:
one or more instructions to compare the predetermined data pattern and the data without using the controller.

19. The non-transitory computer-readable medium of claim 18, wherein the controller outputs a plurality of health check commands based on at least one of:
a periodic interval,
a change in temperature of the non-volatile memory device, or
a quantity of program/erase cycles associated with the non-volatile memory device.

20. The non-transitory computer-readable medium of claim 17, wherein the second data chunk comprises a physical location, of the non-volatile memory device, that is first written when a first write operation is performed on the non-volatile memory device with respect to a sequential order of performing write operations on the non-volatile memory device.
